(19) United States
(12) Patent Application Publication
(10) Pub. No.: US 2024/0105600 A1
(43) Pub. Date: Mar. 28, 2024

(54) WIRING SUBSTRATE, WIRING STRUCTURE USING WIRING SUBSTRATE, ELECTRONIC COMPONENT MOUNTING PACKAGE, AND ELECTRONIC MODULE

(71) Applicant: KYOCERA Corporation, Kyoto-shi (JP)

(72) Inventors: Yoshiki KAWAZU, Kyoto-shi (JP); Tomoya KON, Kyoto-shi (JP); Maraki MAETANI, Kyoto-shi (JP); Ryota FUJIWARA, Kyoto-shi (JP)

(73) Assignee: KYOCERA Corporation, Kyoto-shi (JP)

(21) Appl. No.: 18/474,730

(22) Filed: Sep. 26, 2023

(30) Foreign Application Priority Data
Sep. 28, 2022 (JP) 2022-155074

(51) Int. Cl. H01L 23/528; H01L 23/053; H01L 23/14

(52) U.S. Cl. CPC H01L 23/528; H01L 23/053; H01L 23/142; H01L 23/53295

(57) ABSTRACT

A wiring substrate includes an insulator and first and second conductors. The insulator has a first top surface, a first side surface, and first and second recesses. The first conductor is positioned on the first top surface and has a first end surface. The second conductor is positioned on the first top surface and has a second end surface. The first recess contacts the first and second end surfaces. The second recess is between the first and second conductors. The first recess extends in a second direction and has a first inner side surface and a first bottom surface. The second recess has a second inner side surface and a second bottom surface. The distance from the first top surface to the first bottom surface in a third direction is smaller than the distance from the first top surface to the second bottom surface in the third direction.

### BACKGROUND OF THE INVENTION

### 1. Field of the Invention

The present disclosure relates to a wiring substrate, a wiring structure using a wiring substrate, an electronic component mounting package, and an electronic module.

### 2. Description of the Related Art

In recent years, there has been demand for higher speeds and higher frequencies for signals used to transmit large amounts of information in electronic modules used in wireless communication devices and optical communication devices. Therefore, there is a demand for low-loss transmission of radio-frequency signals in wiring substrates that transmit signals.

In addition, as wireless communication devices and optical communication devices become increasingly smaller in size, the wiring substrates used in these devices, electronic component mounting packages using such wiring substrates, and electronic modules also need to be reduced in size.

For example, as in the invention described in Japanese Unexamined Patent Application Publication No. 2007-5636, as a structure for transmitting radio-frequency signals, a known input/output terminal includes a connection terminal having a line conductor on a top surface thereof and a flexible substrate that includes a wiring conductor and is attached to a dielectric body. The wiring conductor is connected to the line conductor.

However, as electronic modules are further reduced in size, external substrates such as flexible substrates also need to be reduced in size. Therefore, in the invention described in Japanese Unexamined Patent Application Publication No. 2007-5636, the flexible substrate may become detached or displaced from the connection terminal when a force is applied in the direction in which the flexible substrate would become detached.

In addition, the flexible substrate becoming detached or displaced could result in loss occurring in a transmitted signal due to a change in impedance value in the line conductor.

### SUMMARY OF THE INVENTION

In an embodiment of the present invention, (1) a wiring substrate includes an insulator, a first conductor, and a second conductor. The insulator has a first top surface, a first bottom surface opposite the first top surface, and a first side surface positioned between the first top surface and the first bottom surface. The first conductor is positioned on the first top surface, is spaced apart from the first side surface in plan view, and extends in a first direction away from the first side surface. The first conductor has a first end surface that faces the first side surface in plan view. The second conductor is positioned on the first top surface, is spaced apart from the first side surface and the first conductor in plan view, and extends in the first direction. The second conductor has a second end surface that faces the first side surface in plan view. The insulator includes a first recess having a first opening in the first top surface and a second recess having a second opening in the first top surface. The first recess contacts the first end surface and the second end surface in plan view. The second recess is positioned between the first conductor and the second conductor in a second direction that intersects the first direction in plan view. The first recess extends in the second direction and includes a first inner side surface connected to the first top surface and a first bottom surface connected to the first inner side surface. The second recess includes a second inner side surface connected to the first top surface and a second bottom surface connected to second inner side surface. A distance from the first top surface to the first bottom surface in a third direction perpendicular to the first top surface is smaller than a distance from the first top surface to the second bottom surface in the third direction.

(2) In the wiring substrate of (1), the first recess is positioned spaced apart from the first side surface in plan view.

(3) In the wiring substrate of (1), the first recess intersects the first side surface.

(4) In the wiring substrate of any one of (1) to (3), the second inner side surface is connected to the first inner side surface and the first bottom surface.

(5) In the wiring substrate of any one of (1) to (3), the first inner side surface and the second inner side surface are positioned spaced apart from each other.

(6) In the wiring substrate of any one of (1) to (5), a surface roughness of the first bottom surface is greater than a surface roughness of the first top surface.

(7) In the wiring substrate of any one of (4) to (6), the insulator further includes a third recess having a third opening in the second bottom surface. The third recess includes a third inner side surface connected to the second inner side surface and the second bottom surface and includes a third bottom surface connected to the third inner side surface. A distance from the second bottom surface to the third bottom surface in the third direction is smaller than a distance from the first top surface to the second bottom surface in the third direction.

(8) In the wiring substrate of any one of (4) to (7), a distance from the second bottom surface to the third bottom surface in the third direction is identical to a distance from the first top surface to the first bottom surface in the third direction.

In an embodiment of the present invention, (9) a wiring structure includes the wiring substrate of any one of (1) to (8), an external substrate, and bonding material. The bonding material bonds the wiring substrate and the external substrate to each other. The external substrate includes a base portion having a first surface facing the first top surface, and a first external conductor and a second external conductor positioned on the first surface. The first external conductor and the first conductor are electrically connected to each other. The second external conductor and the second conductor are electrically connected to each other. The bonding material is at least partially located in the first recess. The bonding material bonds the first bottom surface and the first surface to each other.

(10) In the wiring structure of (9), the bonding material has a first inclined surface that is inclined from the first bottom surface to the first surface in a direction away from the first side surface in a cross-sectional view along the first direction passing through the first top surface.

In an embodiment of the present invention, (11) a wiring structure includes the wiring substrate of any one of (1) to (8), an external substrate, and bonding material. The bonding material bonds the wiring substrate and the external substrate to each other. The external substrate includes a base portion having a first surface facing the first top surface and a first external conductor and a second external conductor positioned on the first surface. The first external conductor and the first conductor are electrically connected to each other. The second external conductor and the second conductor are electrically connected to each other. The bonding material is at least partially located in the first recess. The bonding material has a second inclined surface that is connected to the first side surface and is inclined from the first bottom surface to the first surface in a direction away from the first side surface in a cross-sectional view along the first direction passing through the first top surface.

In an embodiment of the present invention, (12) an electronic component mounting package includes the wiring substrate of any one of (1) to (8), a base, and a frame. The frame is bonded to a top of the base. The wiring substrate is fixed to the frame.

In an embodiment of the present invention, (13) an electronic component mounting package includes the wiring structure of any one of (9) to (11), a base, and a frame. The frame is bonded to a top of the base. The wiring structure is fixed to the frame.

In an embodiment of the present invention, (14) an electronic module includes the electronic component mounting package of (12), an electronic component, and a lid. The electronic component is positioned on the base and is electrically connected to the wiring substrate. The lid is positioned on the frame and is positioned covering an inside of the electronic component mounting package.

In an embodiment of the present invention, (15) an electronic module includes the electronic component mounting package of (13), an electronic component, and a lid. The electronic component is positioned on the base and is electrically connected to the wiring structure. The lid is positioned on the frame and is positioned covering an inside of the electronic component mounting package.

In an embodiment of the present invention, the wiring substrate of (1) has the above-described configuration, and as a result, the possibility of signal power loss can be reduced while reducing the possibility of an external substrate becoming detached or displaced from the wiring substrate.

### BRIEF DESCRIPTION OF THE DRAWINGS

FIG. 1 is an exploded perspective view of a wiring substrate, a wiring structure, an electronic component mounting package, and an electronic module according to an embodiment of the present invention in which an external substrate and bonding material have been omitted;

FIG. 2 is an enlarged view of a main part II illustrated in FIG. 1;

FIG. 3 is a plan view of a main part III illustrated in FIG. 2;

FIG. 4 is a sectional view along IV-IV of the main part III illustrated in FIG. 2;

FIG. 5 is an enlarged view of a main part V illustrated in FIG. 4;

FIG. 6 is a sectional view along VI-VI of the main part III illustrated in FIG. 2;

FIG. 7 is a perspective view illustrating Variation 1 of a first recess in a wiring substrate illustrated in FIG. 2;

FIG. 8 is a sectional view along VIII-VIII of a main part illustrated in FIG. 7;

FIG. 9 is an enlarged view of a main part IX illustrated in FIG. 8;

FIG. 10 is a sectional view along X-X of the main part illustrated in FIG. 7;

FIG. 11 is a perspective view illustrating Variation 1 of a second recess in the wiring substrate illustrated in FIG. 2;

FIG. 12 is a plan view of a main part XII illustrated in FIG. 11;

FIG. 13 is a sectional view along XIII-XIII of the main part XII illustrated in FIG. 11;

FIG. 14 is a perspective view illustrating Variation 2 of a second recess in the wiring substrate illustrated in FIG. 2;

FIG. 15 is a plan view of a main part illustrated in FIG. 14; and

FIG. 16 is a sectional view along XVI-XVI of the main part illustrated in FIG. 14.

### DESCRIPTION OF THE PREFERRED EMBODIMENTS

### Configuration of Wiring Substrate

Hereinafter, a number of exemplary embodiments of the present invention will be described while referring to the drawings. Although any direction may be considered to be up or down with respect to a wiring substrate, for convenience, a Cartesian coordinate system xyz is defined and the positive side of the z direction is considered to be up. Hereinafter, a first direction, for example, refers to the x direction in the drawings. A second direction intersecting the first direction, for example, refers to a y direction in the drawings. A third direction, for example, refers to a z direction in the drawings. In the present disclosure, a plan view is a concept that includes a planar perspective view.

In variations of a first recess 11 and a second recess 12, only those having different configurations from the first recess 11 and second recess 12 in the embodiment will be described, and other configurations will be denoted by the same or similar symbols as in the embodiment and description thereof will be omitted.

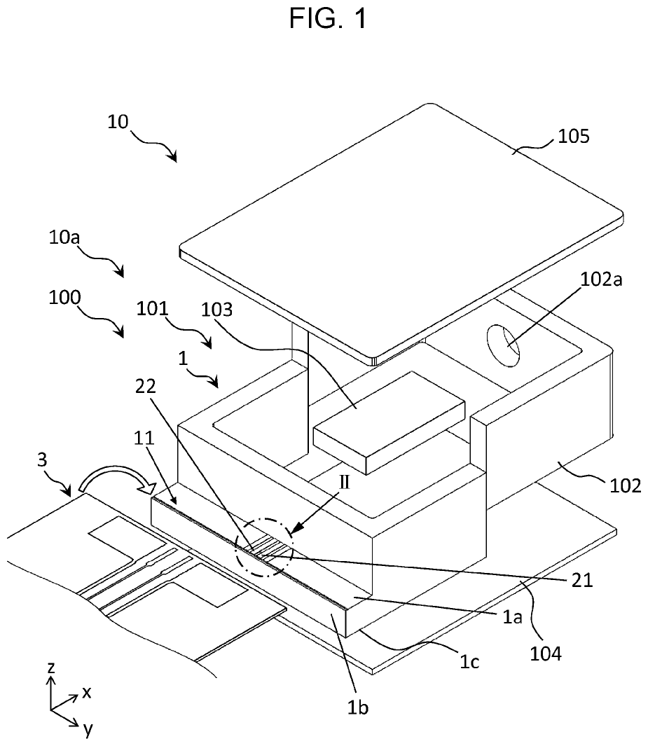

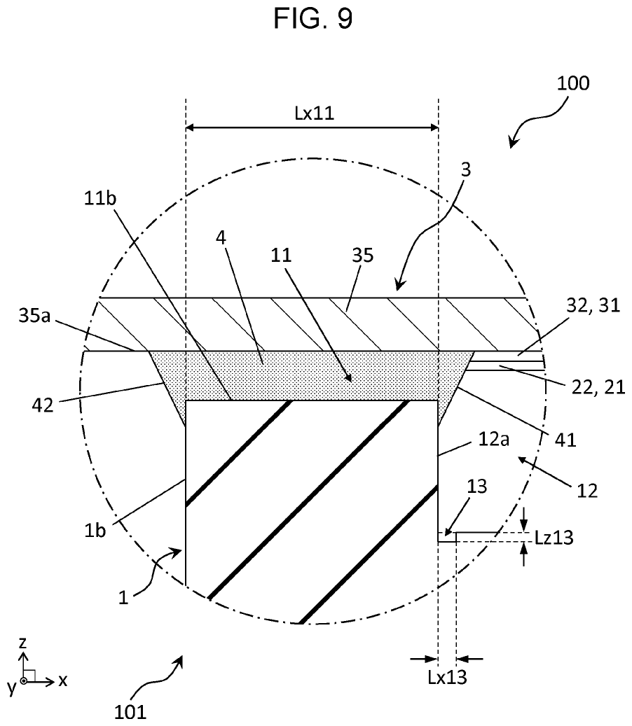

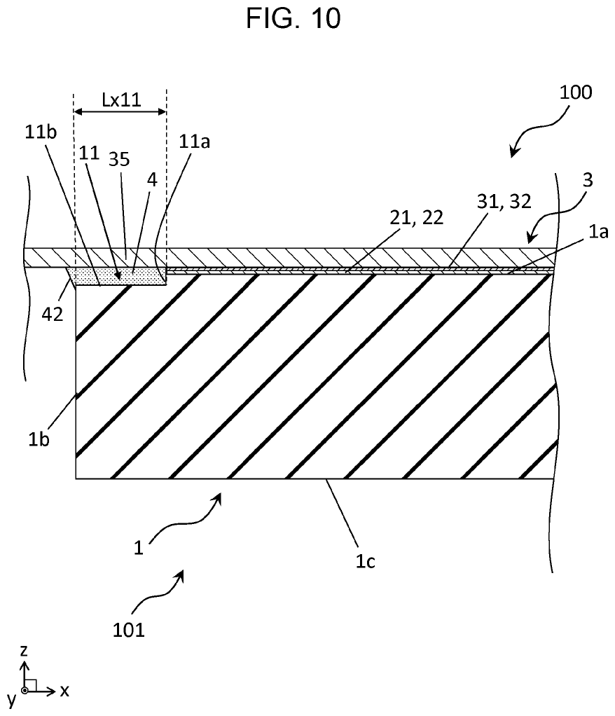

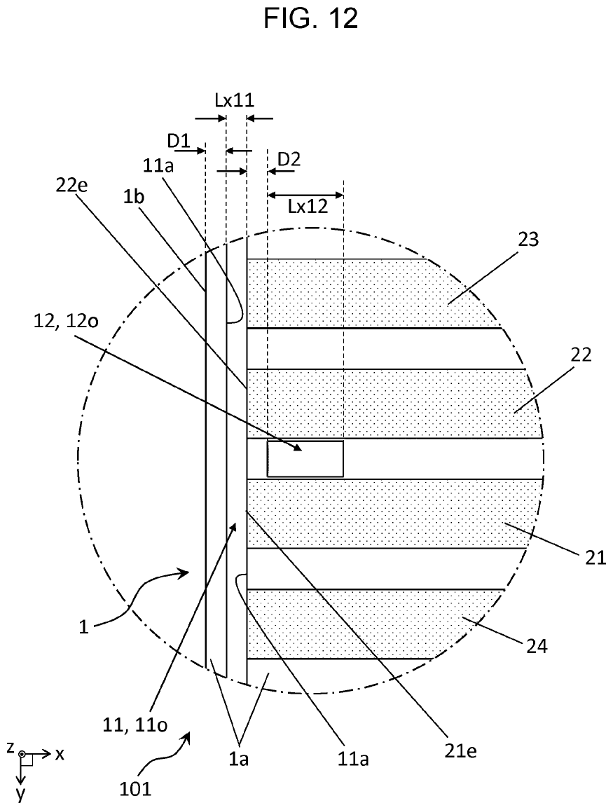

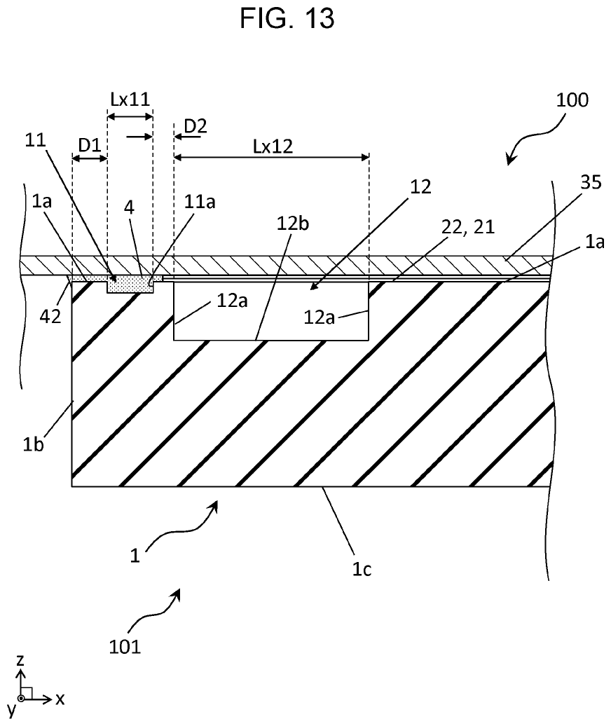

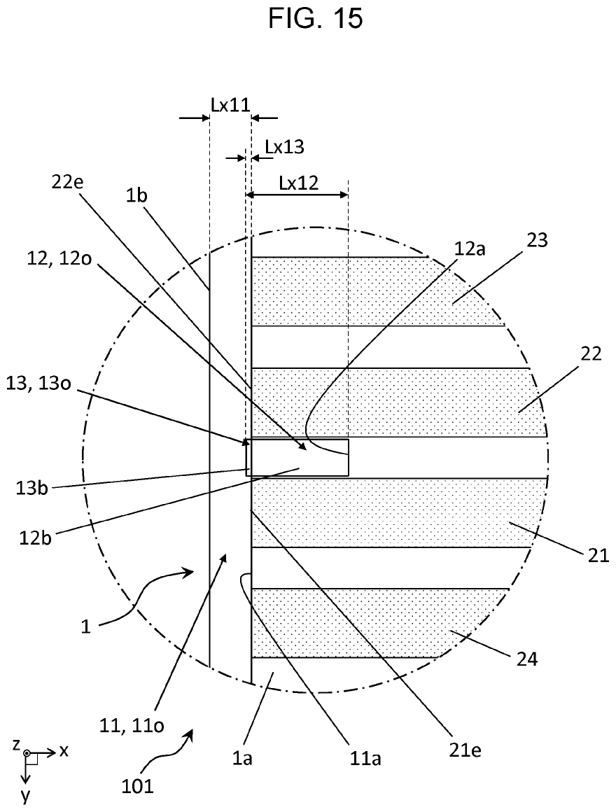

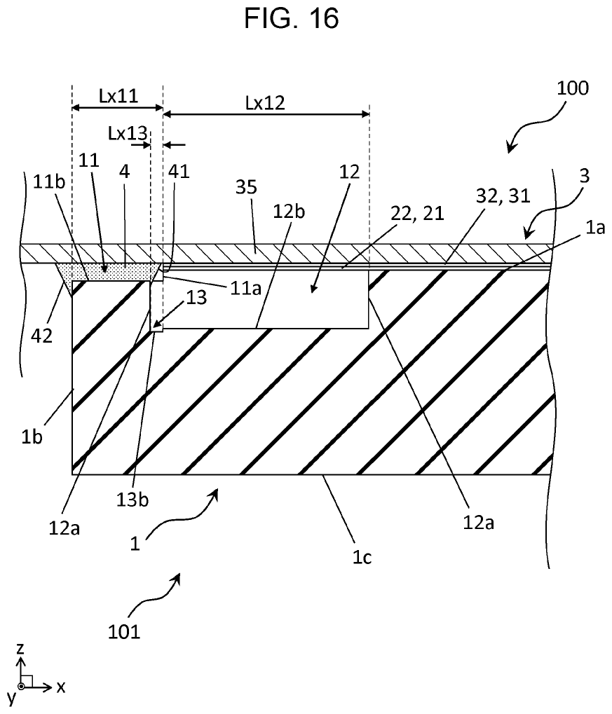

A wiring substrate 101 according to an embodiment of the present invention will be described while referring to FIGS. 1 to 16. In some of the drawings, an external substrate 3 and bonding material 4 are omitted for convenience.

The wiring substrate 101 includes an insulator 1, a first conductor 21, and a second conductor 22.

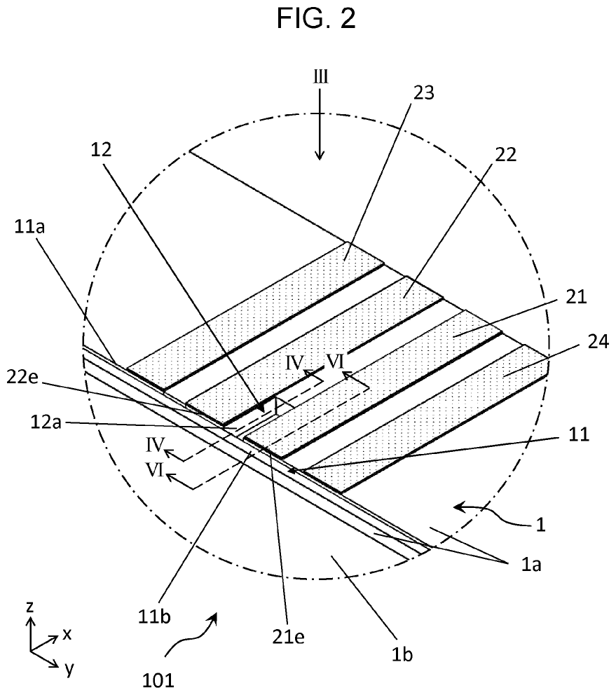

As illustrated in FIGS. 2 to 4, the insulator 1 has a first top surface 1a, a first bottom surface 1c on an opposite side from the first top surface 1a, and a first side surface 1b positioned between the first top surface 1a and the first bottom surface 1c. In this embodiment, the first top surface 1a is divided into two regions by a first recess 11, which is described below, but the two regions (first top surface 1a) are located on the same xy-plane. When the first top surface 1a is divided into multiple regions, the multiple regions do not necessarily need to lie on the same xy-plane. In this embodiment, the first side surface 1b is connected to the first top surface 1a and the first bottom surface 1c.

For example, a ceramic material such as sintered aluminum oxide, sintered mullite, sintered silicon carbide, sintered aluminum nitride or sintered silicon nitride, or a dielectric material such as a glass ceramic material or a glass epoxy material can be used as the material of the insulator 1.

The insulator 1 may consist of a single layer or may have a configuration in which multiple insulating layers are stacked. The insulator 1 is, for example, rectangular in plan view, has dimensions of 4 mm×4 mm to 50 mm×50 mm, and a thickness of 0.5 mm to 10 mm.

The insulator 1 can be manufactured, for example, as follows. Multiple green sheets formed into the outline of the insulator 1 are prepared by processing multiple green sheets using dies and so on. Next, the multiple green sheets are stacked on top of one another with their outer edges aligned so as to form a green sheet multilayer body. The insulator 1 can be obtained by firing the green sheet multilayer body in order to sinter the multiple green sheets.

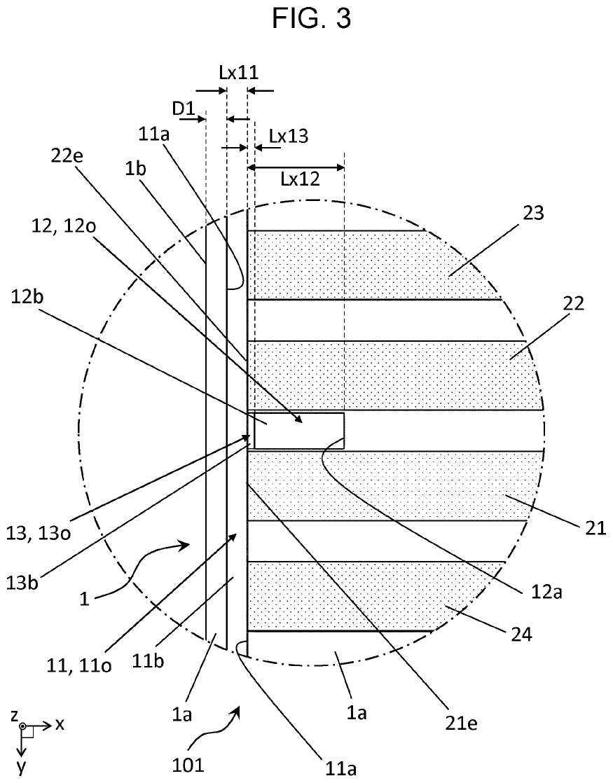

As illustrated in FIGS. 2 and 3, the first conductor 21 is positioned on the first top surface 1a, is spaced apart from the first side surface 1b in plan view, and extends in the first direction (x direction) away from the first side surface 1b. The first conductor 21 has a first end surface 21e that faces the first side surface 1b in plan view. The material of the first conductor 21 is, for example, a metallic material such as gold, silver, copper, nickel, tungsten, molybdenum, or manganese. The first conductor 21 may be formed by sintering a metal paste on the first top surface 1a, or by using a thin film formation technique such as vapor deposition or sputtering.

The first conductor 21 has, for example, a length of 1.5 mm to 25 mm and a width of 0.05 mm to 2 mm. The thickness of the first conductor 21 is, for example, from 0.01 to 0.1 mm. The length, width, and thickness of the first conductor 21 here can be the dimensions of the first conductor 21 in the x direction, y direction, and z direction, respectively.

The second conductor 22 is positioned on the first top surface 1a, is spaced from the first side surface 1b and the first conductor 21 in plan view, and extends in the x direction. The second conductor 22 has a second end surface 22e that faces the first side surface 1b in plan view. The material of the second conductor 22 may be the same as or different from the material of the first conductor 21, for example, a material the same as or similar to the material of the first conductor 21 described above. The first conductor 21 and the second conductor 22 do not necessarily need to be composed of the same or similar materials, and may be composed of different materials. The second conductor 22 may be formed using the same or a similar method to the first conductor 21 described above.

The length, width, and thickness of second conductor 22 may be the same as or different from the length, width, and thickness of first conductor 21, respectively.

Both the first conductor 21 and the second conductor 22 may be signal conductors that transmit electrical signals or ground conductors. Either one of the first conductor 21 and the second conductor 22 may be a ground conductor and the other one may be a signal conductor. When both the first and second conductors 21 and 22 are signal conductors, the first and second conductors 21 and 22 form a pair of differential signal lines. Differential signal lines can reduce the possibility of a signal being affected by noise compared to a single-ended signal line.

Metal plating such as nickel plating or gold plating may be formed on the surface of the first conductor 21. In addition, an insulating film, such as one composed of a ceramic (for example, alumina coating) or resin, may be positioned on part of the first conductor 21. The insulating film can be provided on the first conductor 21 by performing screen printing. The insulating film may be positioned on only part of the first conductor 21. With this configuration, the possibility of the first conductor 21 short-circuiting with other wiring lines can be reduced. The second conductor 22 may have the same or a similar configuration to the first conductor 21 described above.

As illustrated in FIGS. 2 and 3, the wiring substrate 101 may further include a third conductor 23 and a fourth conductor 24 respectively positioned next to the first conductor 21 and the second conductor 22. In this embodiment, the third conductor 23 is positioned on the opposite side of the second conductor 22 from the first conductor 21. The fourth conductor 24 is positioned on the opposite side of the first conductor 21 from the second conductor 22. In this embodiment, the wiring substrate 101 includes both the third conductor 23 and the fourth conductor 24, but may instead just include one of these conductors.

In this embodiment, the first conductor 21 and the second conductor 22 are both signal conductors, and form a pair of differential signal lines. In this embodiment, the third conductor 23 and the fourth conductor 24 are both ground conductors. This configuration allows the ground potential to be further strengthened and reduces the possibility of crosstalk and resonance caused by the electric field distribution being wider than desired when transmitting radio-frequency signals.

Although not illustrated, an inner conductor may be provided inside the insulator 1. In this case, the inner conductor may be a ground conductor and may be electrically connected to ground conductors positioned on the first top surface 1a (third conductor 23 and fourth conductor 24 in this embodiment) by vias or the like. The first recess 11 and/or second recess 12, described below, may be positioned so as to overlap the inner ground conductor in plan view.

As illustrated in FIGS. 2 and 3, the insulator 1 includes the first recess 11 having a first opening 11o in the first top surface 1a and the second recess 12 having a second opening 12o in the first top surface 1a. The first recess 11 and second recess 12 may be formed by performing a punching process on the insulator 1 before sintering, or by performing a known hole forming process such as drilling or blasting on the insulator 1 after sintering.

In this embodiment, a dimension Lx11 of the first recess 11 in the x direction is smaller than a dimension Lx12 of the second recess 12 in the x direction. With this configuration, the wiring substrate 101 can be reduced in size while improving the bonding strength between the insulator 1 and the external substrate 3 in the bond with an external substrate 63, which is described later. In addition, the process of forming the first recess 11 can be shortened because the first recess 11 only needs to be formed in a necessary area. Therefore, manufacture of the wiring substrate 101 can be simplified. The dimension Lx11 of the first recess 11 in the x direction may be the same as or larger than the dimension Lx12 of the second recess 12 in the x direction.

The first recess 11 contacts the first end surface 21e and the second end surface 22e in plan view. With this configuration, the volume of the insulator 1 near the first end surface 21e of the first conductor 21 and near the second end surface 22e of the second conductor 22 can be reduced, and as a result the wiring substrate 101 can be reduced in size. The first recess 11 may be shaped like a groove extending along the first side surface 1b of the insulator 1. The groove may extend along the entirety of the first top surface 1a in the y direction or only along a portion of the first top surface 1a in the y direction. The first recess 11 may be discontinuous partway therealong.

As illustrated in FIG. 3, in this embodiment, the first end surface 21e and the second end surface 22e are straight lines along the y direction in plan view, but the first end surface 21e and the second end surface 22e may be, for example, curved in plan view provided that at least part of each of the first and second end surfaces 21e and 22e contacts the first recess 11.

As illustrated in FIG. 3, the second recess 12 is positioned between the first conductor 21 and the second conductor 22 in the second direction (y direction), which intersects the x direction in plan view. With this configuration, the volume of the insulator 1 located between the first and second conductors 21 and 22 in the y direction in plan view can be reduced. The second recess 12 is filled with air or a dielectric material such as a resin material or a glass material and has a lower dielectric constant than the insulator 1. Therefore, in the case where the first conductor 21 and/or the second conductor 22 are signal conductors, the possibility of signal power being lost during transmission of signals can be reduced.

In this embodiment, the second recess 12 is positioned so as to be spaced apart from the first conductor 21 and the second conductor 22. In this case, the possibility of damage to the first conductor 21 and/or second conductor 22 occurring due to misalignment in the punching process when forming the second recess 12 by performing a punching process using a metal pin or the like can be reduced. The second recess 12 may also be in contact with either or both of the first conductor 21 and the second conductor 22. Although there is only one second recess 12 in this embodiment, multiple second recesses 12 may be positioned between the first conductor 21 and the second conductor 22.

As illustrated in FIGS. 2 and 3, the first recess 11 extends in the y direction. The first recess 11 includes a first inner side surface 11a connected to the first top surface 1a and a first bottom surface 11b connected to the first inner side surface 11a. More specifically, a portion of the first inner side surface 11a is positioned in plan view so as to be continuous with the first end surface 21e and the second end surface 22e. In other words, a portion of the first inner side surface 11a is flush with the first end surface 21e and the second end surface 22e.

As illustrated in FIGS. 2 to 6, the second recess 12 includes a second inner side surface 12a connected to the first top surface 1a and a second bottom surface 12b connected to the second inner side surface 12a. In this embodiment, a portion of the second inner side surface 12a is positioned so as to be continuous with a portion of the first inner side surface 11a.

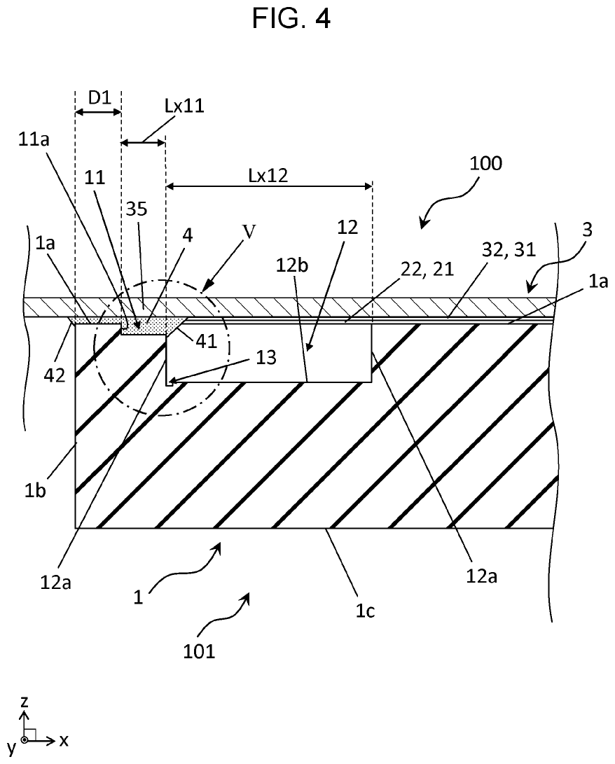

In this embodiment, in plan view, the first opening 11o and the second opening 12o are rectangular, but the first opening 11o and the second opening 12o may instead be oval, square, or rectangular with rounded corners. As illustrated in FIG. 4, the first recess 11 and second recess 12 are rectangular in a cross-sectional view along the x direction passing through the first top surface 1a, but may instead be oval, square, or rectangular with rounded corners. The insulator 1 may also include a third recess 13, which is described below. In this case, the third recess 13 may be positioned inside the second recess 12 in plan view.

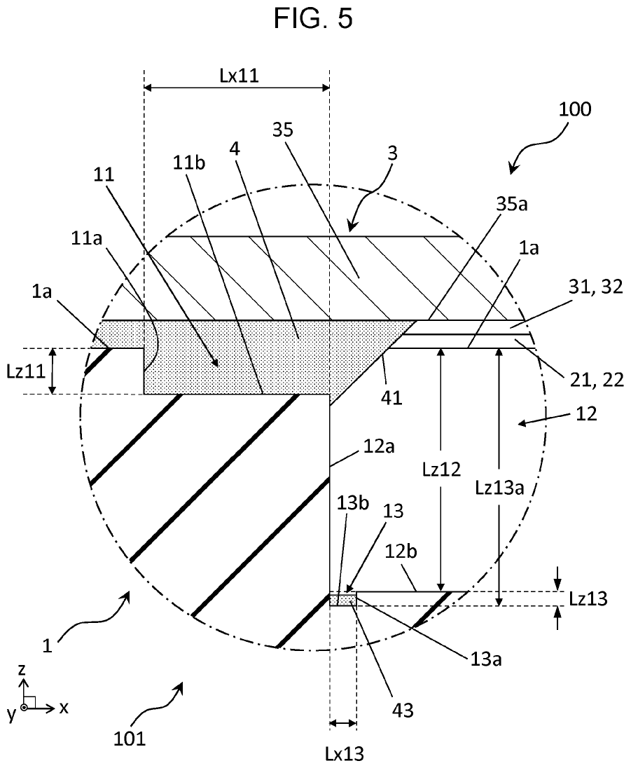

When the insulator 1 is formed by stacking multiple insulating layers, the first recess 11 and the second recess 12 may both be formed only in the insulating layer that is the surface layer, or only the first recess 11 may be formed in the insulating layer that is the surface layer and the second recess 12 may be formed so as to extend across the insulating layer that is the surface layer and an insulating layer therebelow. As illustrated in FIGS. 4 and 5, a distance Lz11 from the first top surface 1a to the first bottom surface 11b in the third direction (z direction) perpendicular to the first top surface 1a is smaller than a distance Lz12 from the first top surface 1a to the second bottom surface 12b in the z direction. The distance Lz11 from the first top surface 1a to the first bottom surface 11b in the z direction may also be referred to as the depth of the first recess 11. The distance Lz12 from the first top surface 1a to the second bottom surface 12b in the z direction may also be referred to as the depth of the second recess 12. With this configuration, the bonding material 4 can be positioned inside the first recess 11 when bonding the external substrate 3, which is described later, to the insulator 1 using the bonding material 4, and therefore the bonding area of the bonding material 4 can be increased and the bonding strength of the external substrate 3 to the insulator 1 can be improved. The “distance Lz11” here refers to the largest distance from the first top surface 1a to the first bottom surface 11b in the z direction, for example, when the depth of the first recess 11 is not constant. The distance Lz12 can be defined in the same way.

The depth of the first recess 11 (Lz11), which is located on the first side surface 1b side, is smaller than the depth of the second recess 12 (Lz12), and therefore the strength of the insulator 1 near the first side surface 1b can be improved.

As illustrated in FIG. 4, the first recess 11 may be positioned so as to be spaced apart from the first side surface 1b in plan view. This configuration allows the bonding material 4 to collect in the first recess 11, thereby reducing the possibility of the bonding material 4, which is described below, flowing onto the first side surface 1b. A smallest distance D1 from the first side surface 1b to the first inner side surface 11a in the x direction may be larger than, smaller than, or the same as the dimension Lx11 of the first recess 11 in the x direction.

As illustrated in FIGS. 2, 4, and 5, the second inner side surface 12a may be connected to the first inner side surface 11a and the first bottom surface 11b. In other words, in this embodiment, in plan view, a portion of the first inner side surface 11a is located on the same straight line in the y direction as a portion of the second inner side surface 12a.

The surface roughness of the first bottom surface 11b may be greater than the surface roughness of the first top surface 1a. This configuration allows the bonding material 4, which is described below, to be more firmly bonded to the first bottom surface 11b due to an anchoring effect. This improves the bonding strength of the external substrate 3 to the insulator 1. The surface roughness is expressed, for example, as arithmetic mean roughness Ra. The surface roughness, expressed as arithmetic mean roughness Ra, can be obtained for example according to JIS B 0601 (2001). Specifically, the surface roughness can be obtained by applying a laser surface roughness measuring machine or the like to the surface to be measured.

As illustrated in FIGS. 3 to 5, the insulator 1 may further include a third recess 13 having a third opening 13o in the second bottom surface 12b. The third recess 13 has a third inner side surface 13a connected to the second inner side surface 12a and the second bottom surface 12b, and a third bottom surface 13b connected to the third inner side surface 13a. In this case, a distance Lz13 from the second bottom surface 12b to the third bottom surface 13b in the z direction may be smaller than the distance Lz12 from the first top surface 1a to the second bottom surface 12b in the z direction. More specifically, the third inner side surface 13a of the third recess 13 is flush with the second inner side surface 12a that is closest thereto in the x direction. With this configuration, the possibility of impedance mismatching occurring between the first conductor 21 and the second conductor 22 can be reduced, because if the bonding material 4, which is described below, drips down into the second recess 12, the bonding material 43 that has dripped down can be collected in the third recess 13. Since the distance Lz13 from the second bottom surface 12b to the third bottom surface 13b in the z direction is smaller than the distance Lz12 from the first top surface 1a to the second bottom surface 12b in the z direction, the possibility of a reduction in the strength of the insulator 1 can be reduced.

The distance Lz11 from the first top surface 1a to the first bottom surface 11b in the z direction may be the same as or different from the distance Lz13 from the second bottom surface 12b to the third bottom surface 13b in the z direction. When the distance Lz11 is the same as the distance Lz13, the insulator 1 can be easily processed and the wiring substrate 101 can be easily manufactured.

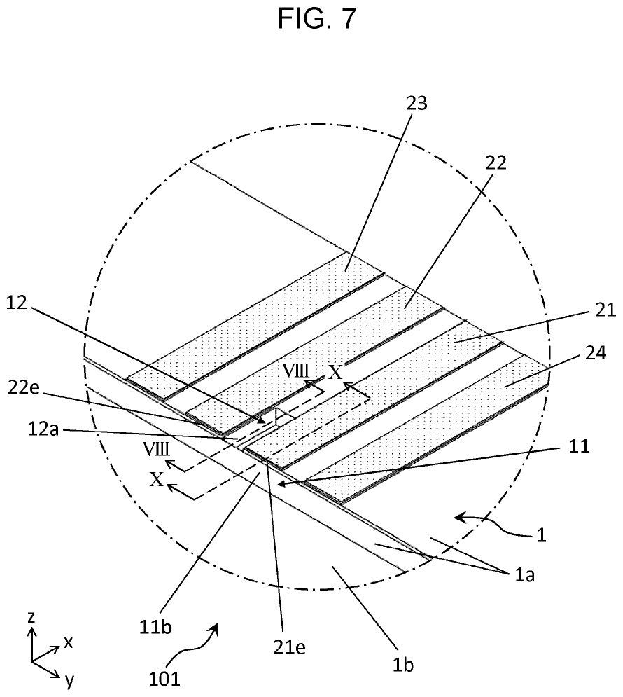

FIGS. 7 to 10 illustrate Variation 1 of the first recess 11. Thus, the first recess 11 may intersect the first side surface 1b. In other words, the first bottom surface 11b is connected to the first side surface 1b. The first recess 11 can also be said to be shaped like a groove cut out from the first top surface 1a to the first side surface 1b. With this configuration, the area where the bonding material 4, which is described below, contacts the first recess 11 can be increased. This improves the bonding strength of the external substrate 3 to the insulator 1.

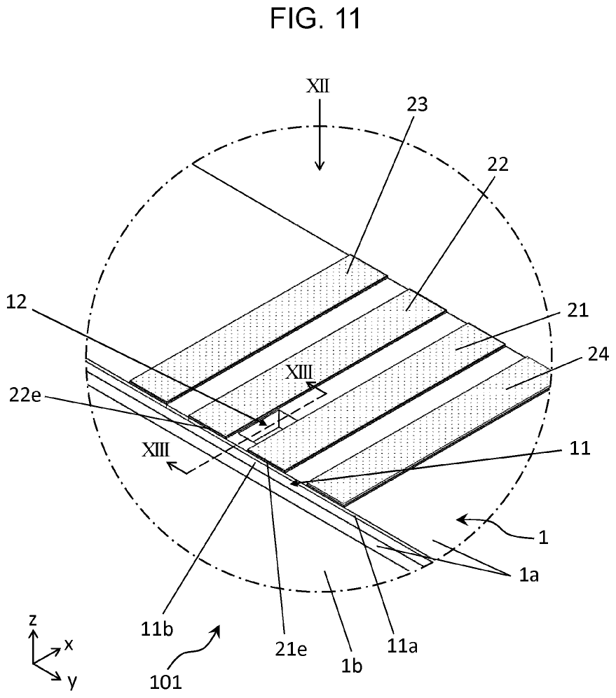

FIGS. 11 to 13 illustrate Variation 1 of the second recess 12. In this way, the first inner side surface 11a and the second inner side surface 12a may be positioned so as to be spaced apart from each other. In other words, in plan view, first recess 11 and second recess 12 are positioned so as to be spaced apart from each other and are not connected. In this case, in the x direction, the first inner side surface 11a and the second inner side surface 12a are positioned a distance D2 apart from each other. A smallest distance D2 from the first inner side surface 11a to the second inner side surface 12a in the x direction may be larger than, smaller than, or the same as the dimension Lx11 of the first recess 11 in the x direction. If the distance D2 is greater than the dimension Lx11, the possibility of reduced strength in the region between the first inner side surface 11a and the second inner side surface 12a can be reduced. Therefore, the possibility of damage such as cracks occurring in the insulator 1 can be reduced. A smallest distance D2 from the first inner side surface 11a to the second inner side surface 12a in the x direction may be larger than, smaller than, or the same as the dimension Lx12 of the second recess 12 in the x direction. Furthermore, if the first recess 11 is positioned so as to be spaced apart from the first side surface 1b in plan view, the smallest distance D2 between the first inner side surface 11a and the second inner side 12a in the x direction may be the same as or different from the smallest distance D1 from the first side surface 1b to the first inner side surface 11a in the x direction.

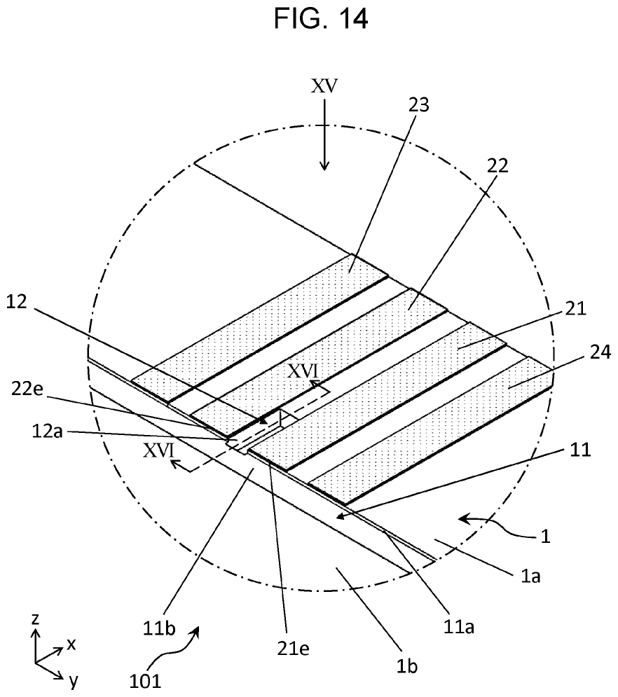

FIGS. 14 to 16 illustrate Variation 2 of the second recess 12. In this variation, a portion of the second recess 12 is positioned so as to overlap the first recess 11 in plan view. The first recess 11 and third recess 13 may be said to be overlapping. With this configuration, the first recess 11 and third recess 13 can be created in succession, and manufacture of wiring substrate 101 can be simplified. The second recess 12 may intersect the first side surface 1b.

Configuration of Wiring Structure

As illustrated in FIGS. 4 to 6, a wiring structure 100 includes the wiring substrate 101, the external substrate 3, and the bonding material 4 that bonds the wiring substrate 101 and the external substrate 3 to each other.

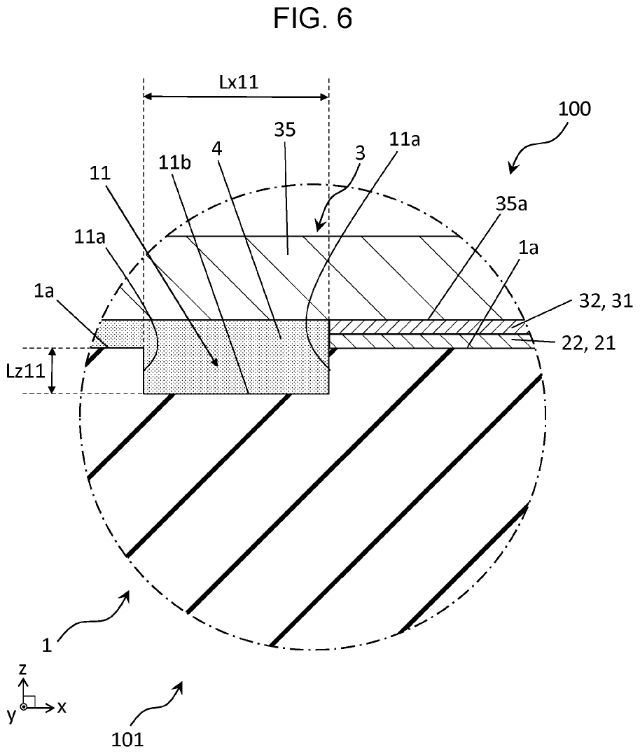

As illustrated in FIGS. 5 and 6, the external substrate 3 includes a base portion 35 having a first surface 35a facing the first top surface 1a, and a first external conductor 31 and a second external conductor 32 positioned on the first surface 35a of the base portion 35. The external substrate 3 may be, for example, a flexible substrate (flexible printed circuit (FPC)) or a printed substrate (printed circuit board (PCB)) on which electronic circuits are formed.

For example, polyimide, a liquid crystal polymer, glass epoxy or Teflon (registered trademark) can be used as the material of the base portion 35. The dielectric constant of the material of the base portion 35 may be from 2 to 5, for example. The base portion 35 is heat resistant to the extent that the base portion 35 can be bonded using solder or a conductive adhesive. The base portion 35 may be flexible.

The material of the first external conductor 31 and the second external conductor 32 may be the same as or different from the material of the first conductor 21, for example, a material the same as or similar to the material of the first conductor 21 described above. The first conductor 21, the first external conductor 31, and the second external conductor 32 do not necessarily need to be composed of the same or similar materials, and may instead be composed of different materials. The first external conductor 31 and the second external conductor 32 may be formed using the same or a similar method to the first conductor 21 described above. The length, width, and thickness of the first external conductor 31 and the second external conductor 32 may respectively be the same as or different from the length, width, and thickness of the first conductor 21.

The first external conductor 31 and the first conductor 21 are electrically connected to each other. Although not illustrated, more specifically, the first external conductor 31 and the first conductor 21 are electrically connected to each other by solder or a brazing material. An adhesive electrically connecting the first external conductor 31 and the first conductor 21 to each other may be the same as or different from the bonding material 4, which is described later. The first external conductor 31 and the first conductor 21 may be electrically connected to each other by a ball grid array (BGA).

The second external conductor 32 and the second conductor 22 are electrically connected to each other. The second external conductor 32 and the second conductor 22 can be electrically connected to each other, for example, by using the same or a similar method to that described above for electrically connecting the first external conductor 31 and the first conductor 21 to each other.

As illustrated in FIGS. 4 to 6, the bonding material 4 may be at least partially located inside the first recess 11. In this case, the bonding material 4 bonds the first bottom surface 11b and the first surface 35a to each other. This configuration allows the area where the bonding material 4 is in contact with the insulator 1 to be increased, and thereby allow the bonding strength of the external substrate 3 to the insulator 1 to be improved.

The material of the bonding material 4 may be, for example, a non-conductive material such as glass or resin, or a conductive material such as solder or a brazing material. If the bonding material 4 is a non-conductive material such as glass or resin, the possibility of changes occurring in the impedance values of the first conductor 21, second conductor 22, first external conductor 31, and second external conductor 32 can be reduced.

As illustrated in FIGS. 5, 9, and 16, the bonding material 4 may have a first inclined surface 41. The first inclined surface 41 is a surface that is inclined from the first bottom surface 11b to the first surface 35a in a direction away from the first side surface 1b in a cross-sectional view along the x direction passing through the first top surface 1a. This configuration allows the area where the bonding material 4 is in contact with the insulator 1 to be increased, and thereby allows the bonding strength of the external substrate 3 to the insulator 1 to be improved. In FIG. 5 and other figures, the first inclined surface 41 is connected to the second inner side surface 12a. In other words, the bonding material 4 may form a fillet from the second inner side surface 12a to the first surface 35a. Although not illustrated, the first inclined surface 41 may be connected to the first bottom surface 11b. In other words, the bonding material 4 may form a fillet from the first bottom surface 11b to the first surface 35a. When the bonding material 4 forms a fillet from the second inner side surface 12a to the first surface 35a, the area where the bonding material 4 contacts the insulator 1 is increased compared to a case where the bonding material 4 forms a fillet from the first bottom surface 11b to the first surface 35a. Therefore, the bonding strength of the external substrate 3 to the insulator 1 can be further improved compared to a case where the fillet is formed from the first bottom surface 11b to the first surface 35a. The “first inclined surface 41” here is not limited to being straight as illustrated in FIG. 5 and so on, and may instead be a curved surface having a convex shape in the negative x-axis direction or the positive x-axis direction.

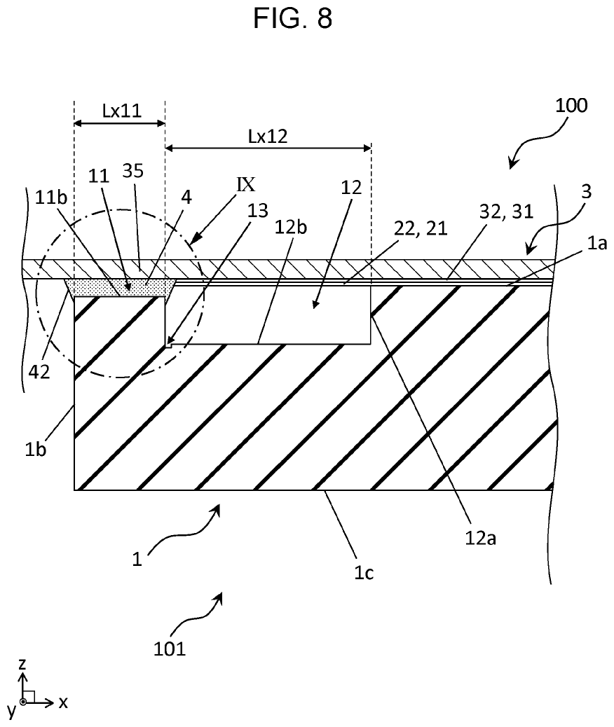

As illustrated in FIGS. 4, 8 to 10, 13, and 16, the bonding material 4 may have a second inclined surface 42. The second inclined surface 42 is a surface that is connected to the first side surface 1b and is inclined from the first bottom surface 11b to the first surface 35a in a direction away from the first side surface 1b in a cross-sectional view along the x direction passing through the first top surface 1a. In other words, the bonding material 4 may form a fillet from the first side surface 1b to the first surface 35a. With this configuration, the bonding strength of the external substrate 3 to the insulator 1 can be improved. When the first recess 11 intersects the first side surface 1b as in Variation 1 of the first recess 1 illustrated in FIGS. 8 to 10, the area of second inclined surface 42 can be increased, and therefore the bonding strength of the external substrate 3 to the insulator 1 can be further improved compared to when the first recess 11 does not intersect the first side surface 1b.

### Configuration of Electronic Component Mounting Package

As illustrated in FIG. 1, an electronic component mounting package 10a according to an embodiment of the present invention includes a wiring substrate 101, a base 104, and a frame 102. The frame 102 is bonded to the base 104. The wiring substrate 101 is fixed to the frame 102. In the electronic component mounting package 10a, the wiring substrate 101 may be the wiring structure 100 connected to the external substrate 3 via the bonding material 4.

The wiring substrate 101 may be bonded to the top surface of the base 104. The base 104 is, for example, rectangular in plan view, has dimensions of 10 mm×10 mm to 50 mm×50 mm, and has a thickness of 0.5 mm to 20 mm. The material of the base 104 is, for example, a metallic material such as copper, iron, tungsten, molybdenum, nickel or cobalt, or an alloy containing any of these metallic materials. In this case, the base 104 may be a single metal plate or a multilayer body in which multiple metal plates are stacked. When the material of the base 104 is a metallic material as described above, a plating layer such as nickel or gold may be formed on the surface of the base 104 using an electroplating or electroless plating method so as to reduce oxidation corrosion. The material of the base 104 may be an insulating material, for example, a ceramic material such as sintered aluminum oxide, sintered mullite, sintered silicon carbide, sintered aluminum nitride, sintered silicon nitride or a glass ceramic.

The base 104 may be a PCB on which electrical circuits are printed. In this case, the wiring substrate 101 may be bonded to base 104 by BGA.

The frame 102 is located on the top surface of the base 104 and protects an electronic component 103 positioned inside the frame 102 in plan view. In other words, in plan view, the frame 102 is positioned so as to surround the electronic component 103. As illustrated in FIG. 1, in this embodiment, the outer edge of the top surface of the base 104 is enclosed by the frame 102 and the wiring substrate 101. Thus, the frame 102 does not need to enclose the entire outer edge of the top surface of the base 104. In this embodiment, the frame 102 is positioned along the outer edge of the top surface of the base 104, but the frame 102 may instead be positioned inward from the outer edge of the top surface of the base 104.

The frame 102 may have a rectangular shape in plan view. In this case, the wiring substrate 101 may be bonded to the bottom surface of the frame 102. Furthermore, when the wiring substrate 101 is bonded to the top surface of the base 104, a structure may be adopted in which the frame 102 and the base 104 sandwich the wiring substrate 101 therebetween.

The material of the frame 102 is, for example, a metallic material such as copper, iron, tungsten, molybdenum, nickel or cobalt, or an alloy containing any of these metallic materials. The material of the frame 102 may be an insulating material, for example, a ceramic material such as sintered aluminum oxide, sintered mullite, sintered silicon carbide, sintered aluminum nitride, sintered silicon nitride or a glass ceramic.

The frame 102 can be bonded to the base 104 via a brazing material or the like. The brazing material may be, for example, silver, copper, gold, aluminum or magnesium, and may contain additives such as nickel, cadmium or phosphorus.

As illustrated in FIG. 1, the frame 102 may include a through hole 102a. Although not illustrated, a fixing member including a translucent window member may be bonded to the through hole 102a. An optical fiber may be inserted into and fixed to the fixing member.

### Configuration of Electronic Module

An electronic module 10 according to an embodiment of the present invention includes the electronic component mounting package 10a, the electronic component 103, and a lid 105. The electronic component 103 is positioned on the base 104 and is electrically connected to the wiring substrate 101. The lid 105 is positioned on the frame 102 and is positioned so as to cover the inside of the electronic component mounting package 10a.

In the electronic module 10, the wiring substrate 101 may be the wiring structure 100 connected to the external substrate 3 via the bonding material 4.

The electronic component 103 may be a component that performs signal processing such as converting an optical signal into an electrical signal or converting an electrical signal into an optical signal. The electronic component 103 is positioned on the top surface of the base 104 and is housed in the electronic component mounting package 10a.

The electronic component 103 may be, for example, an optical semiconductor device such as a semiconductor laser (LD) or a photodiode (PD), a semiconductor integrated circuit device, or a sensor device such as an optical sensor. The electronic component 103 can be formed of a semiconductor material such as gallium arsenide or gallium nitride, for example. When the electronic component 103 is an optical semiconductor device, the electronic module 10 can be used as an optical communication module.

The lid 105 is positioned on the frame 102 so as to cover the inside of the electronic component mounting package 10a, and protects the electronic component 103 together with the frame 102. The lid 105 has, for example, a quadrangular shape in plan view, has dimensions of 10 mm×10 mm to 50 mm×50 mm, and has a thickness of 0.5 mm to 2 mm. The material of the lid 105 is, for example, a metallic material such as iron, copper, nickel, chromium, cobalt, molybdenum, or tungsten, or an alloy of a plurality of any of these metallic materials. The metal member constituting the lid 105 can be fabricated by applying metalworking methods such as rolling and punching methods to an ingot of such a metal material. The electronic module 10 may further include a sealing ring positioned between the lid 105 and the frame 102. The sealing ring functions to join the lid 105 and the frame 102 to each other. The sealing ring is positioned on the frame 102 and surrounds the electronic component 103 in plan view. The material of the sealing ring is, for example, a metallic material such as iron, copper, silver, nickel, chromium, cobalt, molybdenum, or tungsten, or an alloy of a plurality of any of these metallic materials. If no sealing ring is provided on the frame 102, the lid 105 may be joined to the frame 102 via an adhesive such as solder, a brazing material, glass or a resin adhesive for example.

Various combinations of features in this embodiment are not limited to the examples given in the above embodiment. Combinations of embodiments are also possible.

What is claimed is:

1. A wiring substrate comprising:
an insulator having a first top surface, a first bottom surface opposite the first top surface, and a first side surface located between the first top surface and the first bottom surface;
a first conductor positioned on the first top surface, spaced apart from the first side surface in plan view, and extending in a first direction away from the first side surface; and
a second conductor positioned on the first top surface, spaced apart from the first side surface and the first conductor in plan view, and extending in the first direction,
wherein the first conductor has a first end surface facing the first side surface in plan view,
the second conductor has a second end surface facing the first side surface in plan view,
the insulator further includes a first recess having a first opening in the first top surface and contacting the first end surface and the second end surface in plan view, and
a second recess having a second opening in the first top surface and being located between the first conductor and the second conductor in a second direction that intersects the first direction in plan view,
the first recess extends in the second direction and includes a first inner side surface connected to the first top surface and a first bottom surface connected to the first inner side surface,
the second recess includes a second inner side surface connected to the first top surface and a second bottom surface connected to second inner side surface, and
a distance from the first top surface to the first bottom surface in a third direction perpendicular to the first top surface is less than a distance from the first top surface to the second bottom surface in the third direction.

2. The wiring substrate according to claim 1,
wherein the first recess is positioned spaced apart from the first side surface in plan view.

3. The wiring substrate according to claim 1,
wherein the first recess intersects the first side surface.

4. The wiring substrate according to claim 1,
wherein the second inner side surface is connected to the first inner side surface and the first bottom surface.

5. The wiring substrate according to claim 1,
wherein the first inner side surface and the second inner side surface are positioned spaced apart from each other.

6. The wiring substrate according to claim 1,
wherein a surface roughness of the first bottom surface is greater than a surface roughness of the first top surface.

7. The wiring substrate according to claim 4,
wherein the insulator further includes a third recess having a third opening in the second bottom surface,
the third recess has a third inner side surface connected to the second inner side surface and the second bottom surface and has a third bottom surface connected to the third inner side surface, and
a distance from the second bottom surface to the third bottom surface in the third direction is smaller than a distance from the first top surface to the second bottom surface in the third direction.

8. The wiring substrate according to claim 7,
wherein a distance from the second bottom surface to the third bottom surface in the third direction is identical to a distance from the first top surface to the first bottom surface in the third direction.

9. A wiring structure comprising:
the wiring substrate according to claim 1;
an external substrate including a base portion having a first surface facing the first top surface and a first external conductor and a second external conductor positioned on the first surface; and
bonding material at least partially located in the first recess,
wherein the first external conductor and the first conductor are electrically connected to each other,
the second external conductor and the second conductor are electrically connected to each other, and
the bonding material bonds the first bottom surface and the first surface to each other.

10. The wiring structure according to claim 9,
wherein the bonding material has a first inclined surface that is inclined from the first bottom surface to the first surface in a direction away from the first side surface in a cross-sectional view along the first direction passing through the first top surface.

11. A wiring structure comprising:
the wiring substrate according to claim 3;
an external substrate including a base portion having a first surface facing the first top surface and a first external conductor and a second external conductor positioned on the first surface; and
bonding material at least partially located in the first recess,
wherein the first external conductor and the first conductor are electrically connected to each other,
the second external conductor and the second conductor are electrically connected to each other, and
the bonding material has a second inclined surface that is connected to the first side surface and is inclined from the first bottom surface to the first surface in a direction away from the first side surface in a cross-sectional view along the first direction passing through the first top surface.

12. An electronic component mounting package comprising:
a base;
a frame bonded to a top of the base; and
the wiring substrate according to claim 1 fixed to the frame.

13. An electronic component mounting package comprising:
a base;
a frame bonded to a top of the base; and
the wiring structure according to claim 9 fixed to the frame.

14. An electronic module comprising:
the electronic component mounting package according to claim 12;
an electronic component positioned on the base and electrically connected to the wiring substrate; and
a lid positioned on the frame and positioned covering an inside of the electronic component mounting package.

15. An electronic module comprising:
the electronic component mounting package according to claim 13;
an electronic component positioned on the base and electrically connected to the wiring structure; and
a lid positioned on the frame and positioned covering an inside of the electronic component mounting package.
